(19) United States
(12) Patent Application Publication
(10) Pub. No.: US 2025/0311199 A1
(43) Pub. Date: Oct. 2, 2025

(54) SEMICONDUCTOR MEMORY DEVICE

(71) Applicant: Samsung Electronics Co., Ltd., Suwon-si (KR)

(72) Inventors: Joon Young Kang, Suwon-si (KR); Seok Hyun Kim, Suwon-si (KR); Hyo Sun Min, Suwon-si (KR); Jung Gu Han, Suwon-si (KR)

(21) Appl. No.: 18/918,223

(22) Filed: Oct. 17, 2024

(30) Foreign Application Priority Data
Apr. 2, 2024 (KR) 10-2024-0044673

(51) Int. Cl. H10B 12/00

(52) U.S. Cl. CPC H10B 12/485; H10B 12/0335; H10B 12/315; H10B 12/34; H10B 12/482; H10B 12/50

(57) ABSTRACT

A semiconductor memory device includes a substrate, a plurality of contact structures on the substrate, and a fence pattern that separates the plurality of contact structures from each other, where: each of the plurality of contact structures includes a storage contact on the substrate, and a storage pad on the storage contact, the fence pattern includes a filling film and a spacer film including a material that is different from a material of the filling film, the spacer film is between the filling film and the storage contact, and the spacer film is not between the filling film and the storage pad.

### CROSS-REFERENCE TO RELATED APPLICATION

This application claims priority from Korean Patent Application No. 10-2024-0044673 filed on Apr. 2, 2024, in the Korean Intellectual Property Office, the contents of which in its entirety are herein incorporated by reference.

### TECHNICAL FIELD

The present disclosure relates to a semiconductor memory device.

### BACKGROUND

As semiconductor elements become increasingly highly integrated, individual circuit patterns are further miniaturized to realize more semiconductor elements in the same area. That is, as the degree of integration of semiconductor elements increases, design rules for the components of semiconductor elements are reduced.

In highly scaled semiconductor elements, a process of forming a plurality of wiring lines and a plurality of buried contacts (BC) interposed between them becomes increasingly complex and difficult.

### SUMMARY

Aspects of the present disclosure provide a semiconductor memory device in which reliability and performance may be improved.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an example embodiment of the present disclosure, a semiconductor memory device includes substrate, a plurality of contact structures on the substrate, and a fence pattern that separates the plurality of contact structures from each other, where: each of the plurality of contact structures includes a storage contact on the substrate, and a storage pad on the storage contact, the fence pattern includes a filling film and a spacer film including a material that is different from a material of the filling film, the spacer film is between the filling film and the storage contact, and the spacer film is not between the filling film and the storage pad.

According to an example embodiment of the present disclosure, a semiconductor memory device includes a substrate, a cell gate structure that extends in a first direction and includes a cell gate electrode and a cell gate capping film that are in the substrate, a plurality of contact structures on the substrate, and a fence pattern that is on the cell gate structure and is in a trench including side walls that are defined by the plurality of contact structures and a bottom surface defined by the cell gate capping film, where the fence pattern includes a spacer film that extends along a first part of the side walls of the trench and a bottom surface of the trench, and where the fence pattern includes a filling film that is in the trench and is on the spacer film.

According to an example embodiment of the present disclosure, a semiconductor memory device includes a substrate that includes a cell region and a peri-region, a cell region separation film that defines the cell region in the substrate, a cell gate structure that extends in a first direction parallel to a lower surface of the substrate and is in the cell region of the substrate, a plurality of contact structures on the substrate, and a fence pattern that is on the cell gate structure and between the plurality of contact structures, where: each of the plurality of contact structures includes a storage contact on the substrate and a storage pad on the storage contact, a distance between a bottom surface of the fence pattern and a lower surface of the substrate in a second direction perpendicular to the lower surface of the substrate is less than a distance between a bottom surface of the storage contact and the lower surface of the substrate in the second direction, the fence pattern includes a filling film between the plurality of contact structures, the fence pattern includes a spacer film that is between the filling film and the storage contact and is not between the filling film and the storage pad, and the spacer film overlaps the storage pad in the second direction.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a schematic layout showing a cell region of a semiconductor memory device according to some embodiments of the present disclosure;

FIG. 2 is a schematic layout of the semiconductor memory device including the cell region of FIG. 1;

FIG. 3 is a cross-sectional view taken along line A-A of FIG. 1;

FIG. 4 is a cross-sectional view taken along line B-B of FIG. 1;

FIG. 5 is a cross-sectional view taken along line C-C of FIG. 2;

FIG. 6 is a cross-sectional view taken along line C-C of FIG. 2;

FIGS. 7, 8, 9, 10, 11, 12, 13, 14, 15, and 16 are intermediate stage diagrams for explaining a method for explaining the semiconductor memory device according to some embodiments of the present disclosure;

FIG. 17 is a layout diagram for explaining the semiconductor memory device according to some embodiments of the present disclosure;

FIG. 18 is a perspective view for explaining the semiconductor memory device according to some embodiments of the present disclosure;

FIG. 19 is a cross-sectional view taken along lines D-D and E-E of FIG. 17;

FIG. 20 is a layout diagram for explaining the semiconductor memory device according to some embodiments of the present disclosure; and

FIG. 21 is a perspective view for explaining the semiconductor memory device according to some embodiments of the present disclosure.

### DETAILED DESCRIPTION

To clarify the present disclosure, the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the singular forms “a,” “an” and “the” are intended to include the plural forms as well, unless the context clearly indicates otherwise. The term “and/or” includes any and all combinations of one or more of the associated listed items. The term “connected” may be used herein to refer to a physical and/or electrical connection and may refer to a direct or indirect physical and/or electrical connection. The term “exposed” may be used to define a relationship between particular layers or surfaces, but it does not require the layer or surface to be free of other elements or layers thereon in the completed device.

Hereinafter, example embodiments will be explained in detail with reference to the accompanying drawings.

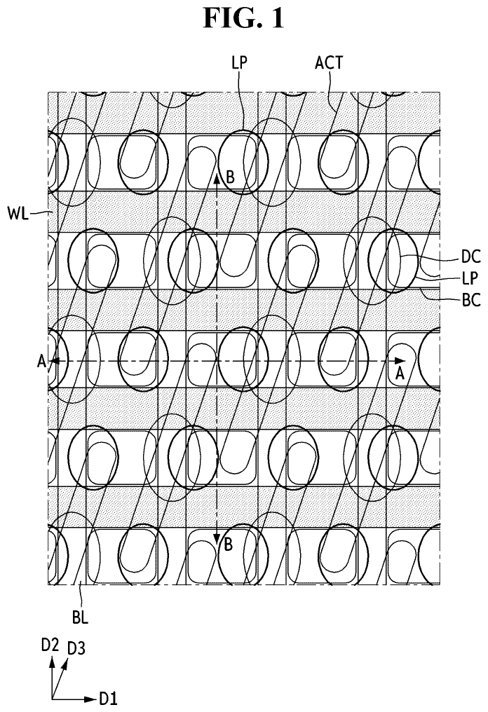

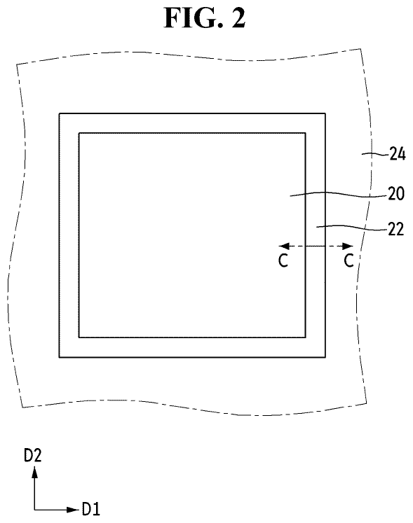

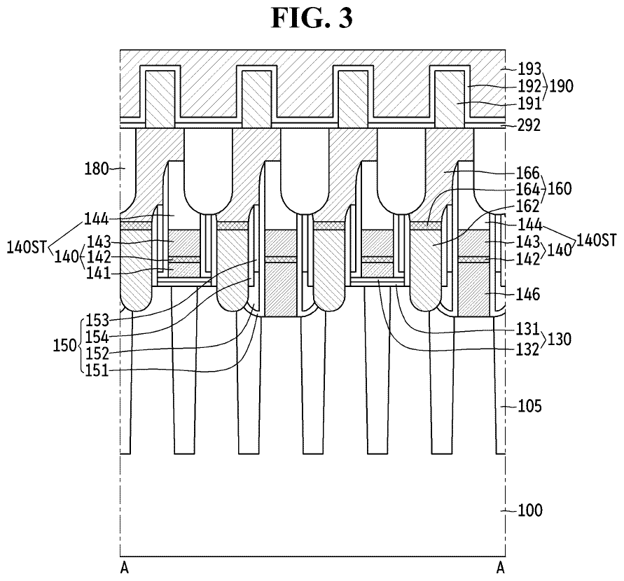

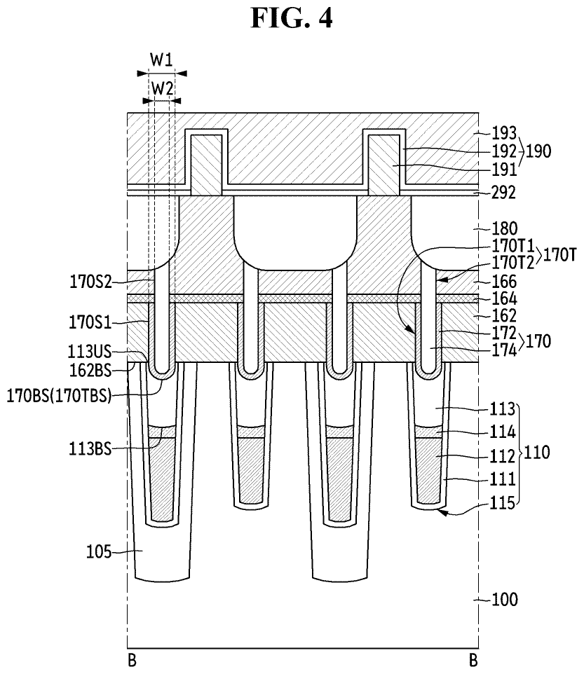

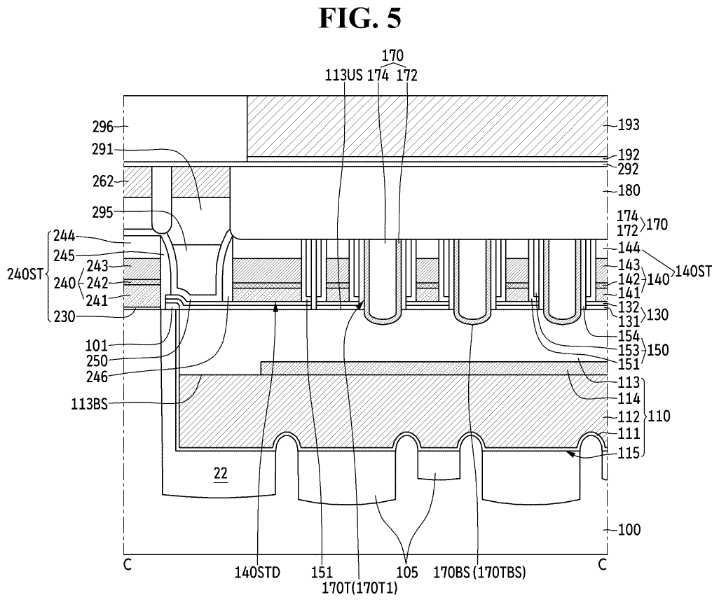

FIG. 1 is a schematic layout showing a cell region of a semiconductor memory device according to some embodiments. FIG. 2 is a schematic layout of the semiconductor memory device including a cell region of FIG. 1. FIG. 3 is a cross-sectional view taken along line A-A of FIG. 1. FIG. 4 is a cross-sectional view taken along line B-B of FIG. 1. FIG. 5 is a cross-sectional view taken along the line C-C of FIG. 2. For reference, FIG. 5 may be a cross-sectional view taken along a word line WL of FIG. 1 in a cell region separation film 22.

Referring to FIGS. 1 to 5, the semiconductor memory device according to some embodiments may include a cell region 20, a cell region separation film 22, and a peri-region 24.

The cell region separation film 22 may be formed along the periphery of the cell region 20. The cell region separation film 22 may separate the cell region 20 and the peri-region 24. The peri-region 24 may be defined around the cell region 20.

The cell region 20 may include a plurality of cell active regions ACT. The cell active region ACT may be defined by a cell element separation film 105 (FIG. 3) formed inside the substrate 100 (FIG. 3). With a decrease in a design rule of the semiconductor memory device, the cell active region ACT may be disposed in a bar shape of a diagonal line or an oblique line shown in the drawing. For example, the cell active region ACT may extend in a third direction D3.

A plurality of gate electrodes may be disposed in the first direction D1 across the cell active region ACT. The plurality of gate electrodes may extend parallel to each other. The plurality of gate electrodes may be, for example, a plurality of word lines WLD. The word lines WL may be disposed at regular intervals. The width of the word lines WL or an interval between the word lines WL may be determined depending on the design rules.

A plurality of bit lines BL extending in a second direction D2 perpendicular to the word line WL may be disposed on the word line WL. The plurality of bit lines BL may extend in parallel between each other. The bit lines BL may be disposed at regular intervals. The width of the bit lines BL or the interval between the bit lines BL may be determined depending on design rules.

The semiconductor memory device according to some embodiments may include various contact arrangements formed on the cell active region ACT. Various contact arrangements may include, for example, a direct contact DC, a buried contact BC, a landing pad LP, and the like.

Here, the direct contact DC may mean a contact that electrically connects the cell active region ACT to the bit line BL. The buried contact BC may refer to a contact that connects the cell active region ACT to a lower electrode 191 (FIG. 3) of the capacitor. Due to the placement structure, the contact area between the buried contact BC and the cell active region ACT may be small. Therefore, in order to expand the contact area with the cell active region ACT and the contact area with the lower electrode 191 of the capacitor (FIG. 3), a conductive landing pad LP may be introduced.

The landing pad LP may be disposed between the buried contact BC and the lower electrode 191 of the capacitor (FIG. 3), or may be disposed between the cell active region ACT and the buried contact BC. In the semiconductor memory device according to some embodiments, the landing pad LP may be disposed between the buried contact BC and the lower electrode 191 of the capacitor. By expanding the contact area through the introduction of the landing pad LP, the contact resistance between the cell active region ACT and the lower electrode 191 (FIG. 3) of the capacitor may be reduced.

The direct contact DC may be connected to a central portion of the cell active region ACT. The buried contact BC may be connected to an end of the cell active region ACT. As the buried contacts BC are disposed at both ends of the cell active region ACT, the landing pads LP may be disposed adjacent to both ends of the cell active region ACT to partially overlap the buried contacts BC. In other words, the buried contact BC may be formed to overlap the cell active region ACT and the cell element separation film 105 (FIG. 3) between the adjacent word lines WL and the adjacent bit lines BL.

The word line WL may be formed in a structure buried inside the substrate 100. The word line WL may be disposed across the cell active region ACT between the direct contact DC and the buried contact BC. As shown, the two word lines WL may be disposed to cross or intersect one cell active region ACT. Since the cell active region ACT extends along the third direction D3, the word line WL may have an angle of less than 90 degrees with respect to the cell active region ACT.

The direct contact DC and the buried contact BC may be disposed symmetrically. Therefore, the direct contact DC and the buried contact BC may be disposed in a straight line along the first direction D1 and the second direction D2.

On the other hand, unlike the direct contact DC and the buried contact BC, the landing pads LP may be disposed in a zigzag shape in the second direction D2 in which the bit line BL extends. Further, the landing pad LP may be disposed to overlap the same side surface portion of each bit line BL in the first direction D1 in which the word line WL extends.

For example, each of the landing pads LP of a first line may overlap a left side surface of the corresponding bit line BL, and each of the landing pads LP of a second line may overlap a right side surface of the corresponding bit line BL.

Referring to FIGS. 1 to 5, a semiconductor memory device according to some embodiments may include a plurality of cell gate structures 110, a plurality of bit line structures 140ST, a plurality of contact structures 160, an information storage element 190, and a peri-gate structure 240ST.

The substrate 100 may include a cell region 20, a cell region separation film 22, and a peri-region 24. The substrate 100 may be a silicon substrate or silicon-on-insulator (SOI). In contrast, the substrate 100 may include, but is not limited to, silicon germanium, silicon germanium on insulator (SGOI), indium antimonide, lead telluride, indium arsenide, indium phosphide, gallium arsenide or gallium antimonide.

The plurality of cell gate structures 110, the plurality of bit line structures 140ST, the plurality of contact structures 160, and the information storage element 190 may be disposed in the cell region 20. The peri-gate structure 240ST may be disposed in the peri-region 24.

The cell element separation film 105 may be formed inside the substrate 100 of the cell region 20. The cell element separation film 105 may have an STI (shallow trench isolation) structure having enhanced element isolation characteristics. The cell element separation film 105 may define a cell active region ACT inside the cell region 20. The cell active region ACT defined by the cell element separation film 105 may have a long island formation including a short axis and a long axis, as shown in FIG. 1. The cell active region ACT may have a diagonal shape to form an angle of less than 90 degrees with respect to the word line WL formed in the cell element separation film 105. Further, the cell active region ACT may have a diagonal shape to form an angle of less than 90 degrees with respect to the bit line BL formed on the cell element separation film 105.

The cell region separation film 22 may also be formed with a cell boundary separation film having an STI structure. The cell region 20 may be defined by the cell region separation film 22.

The cell element separation film 105 and the cell region separation film 22 may each include, for example, at least one of a silicon oxide film, a silicon nitride film, and a silicon oxynitride film. Each of the cell element separation film 105 and the cell region separation film 22 may be one insulating film or a plurality of insulating films. Depending on the widths of the cell element separation film 105 and the cell region separation film 22, each of the cell element separation film 105 and the cell region separation film 22 may be formed of one insulating film or may be formed of a plurality of insulating films.

Although the upper surface of the cell element separation film 105, the upper surface of the substrate 100, and the upper surface of the cell region separation film 22 are shown as being placed on the same plane, this is only for convenience of explanation, and the present disclosure is not limited thereto.

The cell gate structure 110 may be formed inside the substrate 100 and the cell element separation film 105. The cell gate structure 110 may be formed across the cell element separation film 105 and the cell active region ACT defined by the cell element separation film 105. The cell gate structure 110 may include a cell gate trench 115, a cell gate insulating film 111, a cell gate electrode 112, a cell gate capping film 113, and a cell gate capping conductive film 114 formed inside the substrate 100 and the cell element separation film 105. Here, the cell gate electrode 112 may correspond to the word line WL. Unlike the shown example, the cell gate structure 110 may not include the cell gate capping conductive film 114.

The cell gate trench 115 may be relatively deep within the cell element separation film 105 and relatively shallow within the cell active region ACT. A bottom surface of the cell gate electrode 112 may be bent. That is, a depth of the cell gate trench 115 in the cell element separation film 105 relative to an upper surface of the substrate 100 may be greater than a depth of the cell gate trench 115 in the cell active region ACT relative to an upper surface of the substrate 100.

The cell gate insulating film 111 may extend along side walls and bottom surface of the cell gate trench 115. The cell gate insulating film 111 may extend along the profile of at least a part of the cell gate trench 115. The cell gate insulating film 111 may include, for example, at least one of silicon oxide, silicon nitride, silicon oxynitride or a high dielectric constant material having a higher dielectric constant than silicon oxide. The high dielectric constant material may include, for example, at least one of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and combinations thereof.

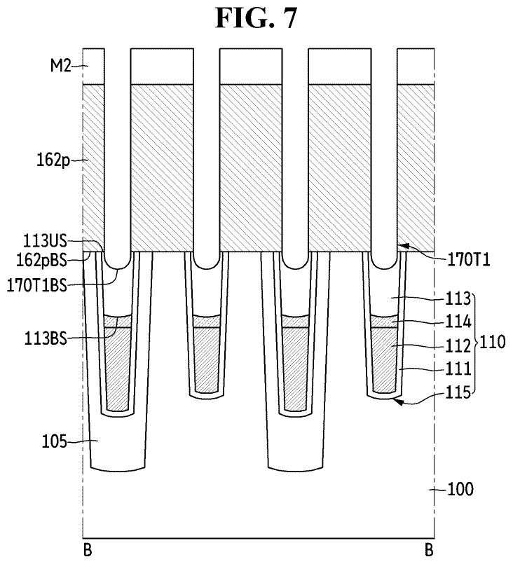

The cell gate electrode 112 may be formed on the cell gate insulating film 111. The cell gate electrode 112 may at least partially fill the cell gate trench 115. The cell gate capping conductive film 114 may extend along the upper surface of the cell gate electrode 112. Although FIG. 7 shows that the cell gate capping conductive film 114 does not cover or overlap a part of the upper surface of the cell gate electrode 112, the present disclosure is not limited thereto.

The cell gate electrode 112 may include at least one of a metal, a conductive metal nitride, a conductive metal carbonitride, a conductive metal carbide, a metal silicide, a doped semiconductor material, a conductive metal oxynitride, and a conductive metal oxide. The cell gate electrode 112 may include, for example, but not limited to, at least one of TiN, TaC, TaN, TiSiN, TaSiN, TaTiN, TiAlN, TaAlN, WN, Ru, TiAl, TiAlC—N, TiAlC, TiC, TaCN, W, Al, Cu, Co, Ti, Ta, Ni, Pt, Ni—Pt, Nb, NbN, NbC, Mo, MoN, MoC, WC, Rh, Pd, Ir, Ag, Au, Zn, V, RuTiN, TiSi, TaSi, NiSi, CoSi, IrOx, RuOx and combinations thereof. The cell gate capping conductive film 114 may include, for example, but is not limited to, polysilicon or polysilicon-germanium.

The cell gate capping film 113 may be disposed on the cell gate electrode 112 and the cell gate capping conductive film 114. The cell gate capping film 113 may at least partially fill the remaining cell gate trench 115 that remains after the cell gate electrode 112 and the cell gate capping conductive film 114 are formed. For example, the cell gate insulating film 111 may extend along side walls of the cell gate capping film 113.

The cell gate capping film 113 may include, for example, at least one of silicon nitride (SiN), silicon oxynitride (SiON), silicon oxide (SiO₂), silicon carbonitride (SiCN), silicon oxycarbonitride (SiOCN), and combinations thereof.

Although not shown, an impurity doped region may be formed on at least one side of the cell gate structure 110. The impurity doped region may be a source/drain region of a transistor.

The bit line structure 140ST may include a cell conductive line 140 and a cell line capping film 144. The cell conductive line 140 may be disposed on the substrate 100 and the cell element separation film 105 on which the cell gate structure 110 is disposed.

The cell conductive line 140 may extend in the second direction D2. The cell conductive line 140 may intersect the cell element separation film 105 and the cell active region ACT defined by the cell element separation film 105. The cell conductive line 140 may be formed to intersect the cell gate structure 110. Here, the cell conductive line 140 may correspond to the bit line BL.

The cell conductive line 140 may include one or more films. The cell conductive line 140 may include, for example, a first cell conductive film 141, a second cell conductive film 142, and a third cell conductive film 143. The first to third cell conductive films 141, 142, and 143 may be sequentially stacked on the substrate 100 and the cell element separation film 105.

Each of the first to third cell conductive films 141, 142, and 143 may include at least one of a semiconductor material doped with impurities, a conductive silicide compound, a conductive metal nitride, a two-dimensional (2D) material, and a metal. In the semiconductor memory device according to some embodiments, the two-dimensional (2D) material may be a metallic material and/or a semiconductor material. The 2D material may include a 2D allotrope or a 2D compound, and may include, but is not limited to, at least one of graphene, molybdenum disulfide (MoS₂), molybdenum diselenide (MoSe₂), tungsten diselenide (WSe₂), and tungsten disulfide (WS₂).

For example, the first cell conductive film 141 may include a doped semiconductor material, the second cell conductive film 142 may include at least one of a conductive silicide compound, a conductive metal nitride, and a two-dimensional material, and the third cell conductive film 143 may include a metal.

The bit line contact 146 may be disposed between the cell conductive line 140 and the substrate 100. That is, the cell conductive line 140 may be disposed on the bit line contact 146. For example, the bit line contact 146 may be formed at a point on which the cell conductive line 140 intersects a central portion of the cell active region ACT having a long island shape. The bit line contact 146 may be disposed between the central portion of the cell active region ACT and the cell conductive line 140.

The bit line contacts 146 may electrically connect the cell conductive line 140 and the substrate 100. Here, the bit line contact 146 may correspond to a direct contact DC. The bit line contact 146 may include, for example, at least one of an impurity-doped semiconductor material, a conductive silicide compound, a conductive metal nitride, and a metal.

The cell conductive line 140 may include a second cell conductive film 142 and a third cell conductive film 143 in a region that overlaps the upper surface of the bit line contact 146. The cell conductive line 140 may include first to third cell conductive films 141, 142, and 143 in a region that does not overlap the upper surface of the bit line contact 146. The thickness of the cell conductive line 140 in the region that overlaps the upper surface of the bit line contact 146 may be different from the thickness of the cell conductive line 140 in the region that does not overlap the upper surface of the bit line contact 146.

The cell line capping film 144 may be disposed on the cell conductive line 140. The cell line capping film 144 may extend along the upper surface of the cell conductive line 140 in the second direction D2. At this time, the cell line capping film 144 may include, for example, at least one of a silicon nitride film, silicon oxynitride, silicon carbonitride, and silicon oxycarbonitride. In the semiconductor memory device according to some embodiments, the cell line capping film 144 may include, for example, a silicon nitride film. The cell line capping film 144 may be a single film, or the cell line capping film 144 may include multiple films. However, if each of the multiple films includes the same material, the cell line capping film 144 may be regarded as a single film.

The cell insulating film 130 may be disposed on the substrate 100 and the cell element separation film 105. More specifically, the cell insulating film 130 may be disposed on the substrate 100 and the cell element separation film 105 on which the bit line contact 146 is not formed. The cell insulating film 130 may be disposed between the substrate 100 and the cell conductive line 140, and between the cell element separation film 105 and the cell conductive line 140.

Although the cell insulating film 130 may be a single film, as shown, the cell insulating film 130 may include multiple films including a first cell insulating film 131 and a second cell insulating film 132. For example, the first cell insulating film 131 may include a silicon oxide film, and the second cell insulating film 132 may include a silicon nitride film. The cell insulating film 130 may include three or more insulating films. When the cell insulating film 130 includes a third cell insulating film, the third cell insulating film may be a silicon oxide film.

A cell buffer film 101 may be disposed between the cell insulating film 130 and the cell region separation film 22. The cell buffer film 101 may include, for example, a silicon oxide film.

A bit line spacer 150 may be disposed on the side walls of the cell conductive line 140 and the cell line capping film 144. The bit line spacer 150 may be disposed on the substrate 100 and the cell element separation film 105 in the portion of the cell conductive line 140 on which the bit line contact 146 is disposed. The bit line spacer 150 may be disposed on the side walls of the cell conductive line 140, the cell line capping film 144, and the bit line contact 146.

In the remaining portion of the cell conductive line 140 in which the bit line contact 146 is not formed, the bit line spacer 150 may be disposed on the cell insulating film 130. The bit line spacer 150 may be disposed on the side walls of the cell conductive line 140 and the cell line capping film 144.

The bit line spacer 150 may be disposed on a long side wall that extends in the second direction D2 among side walls of the bit line structure 140ST.

Although the bit line spacer 150 may be a single film, as shown, the bit line spacer 150 may include multiple films including first to fourth cell line spacers 151, 152, 153, and 154. For example, the first to fourth cell line spacers 151, 152, 153, and 154 may include one of a silicon oxide film, a silicon nitride film, a silicon oxynitride film (SiON), a silicon oxycarbonitride film (SiOCN), an air film, or the like. For example, the second cell line spacer 152 is not disposed on the cell insulating film 130, but may be disposed on the side wall of the bit line contact 146.

For example, the second cell line spacer 152 is not disposed on the cell insulating film 130, but may be disposed on the side wall of the bit line contact 146. In FIG. 7, on the upper surface of the cell gate structure 110, the fourth cell line spacer 154 may extend along the side walls of the cell conductive lines 140 adjacent to each other in the first direction D1 and the upper surface of the cell gate capping film 113.

A dummy bit line structure 140STD may be adjacent to the peri-region 24. The dummy bit line structure 140STD may be disposed on the substrate 100 of the cell region 20 adjacent to the cell region separation film 22 and the peri-region 24. The dummy bit line structure STD may be disposed between the peri-gate structure 240ST closest to the cell region 20 and the bit line structure 140ST closest to the peri-region 24.

The dummy bit line structure 140STD may have the same structure as the bit line structure 140ST. That is, the dummy bit line structure 140STD may include a cell conductive line 140 and a cell line capping film 144.

A first cell line spacer 151 and a third cell line spacer 153 may be formed on the first side wall of the dummy bit line structure 140STD that faces the bit line structure 140ST. A cell boundary spacer 246 may be disposed on a second side wall that is opposite to the first side wall of the dummy bit line structure 140STD in the first direction D1. The cell boundary spacer 246 may be formed at the same level as the peri-spacer 245. Here, “the same level” means that they are formed by the same fabricating process.

A contact structure 160 may be disposed on the substrate 100 of the cell region 20. The contact structure 160 may be connected to the substrate 100. The contact structure 160 may be arranged on the substrate 100 in the first direction D1 and the second direction D2. The contact structure 160 may include a storage contact 162, a contact silicide film 164, and a storage pad 166.

The storage contact 162 may be disposed between the cell conductive lines 140 adjacent in the first direction D1. The storage contact 162 may be disposed between fence patterns 170 adjacent in the second direction D2. The storage contact 162 may overlap the substrate 100 and the cell element separation film 105 between the adjacent cell conductive lines 140. The storage contact 162 may be connected to the end of the cell active region ACT. Here, the storage contact 162 may correspond to the buried contact BC.

The storage contact 162 may include, for example, at least one of an impurity-doped semiconductor material, a conductive silicide compound, a conductive metal nitride, and a metal.

A contact silicide film 164 may be disposed between the storage contact 162 and the storage pad 166. The contact silicide film 164 may include, for example, a conductive silicide compound.

The storage pad 166 may be formed on the storage contact 162. The storage pad 166 may be electrically connected to the storage contact 162 through the contact silicide film 164. Here, the storage pad 166 may correspond to the landing pad LP.

The storage pad 166 may overlap a part of the upper surface of the bit line structure 140ST. The storage pad 166 may include, for example, at least one of an impurity-doped semiconductor material, a conductive silicide compound, a conductive metal nitride, a conductive metal carbide, a metal, and a metal alloy.

A fence pattern 170 may be disposed on the substrate 100 and the cell element separation film 105. The fence pattern 170 may be disposed on the cell gate structure 110. The fence pattern 170 may be formed to overlap the cell gate structure 110 formed inside the substrate 100 and the cell element separation film 105. The fence pattern 170 may be disposed between the adjacent contact structures 160. The fence pattern 170 may separate the contact structures 160. The fence pattern 170 may at least partially fill or be in spaces between the adjacent contact structures 160. The fence pattern 170 may be disposed between the bit line structures 140ST extending in the second direction D2. The fence pattern 170 may at least partially fill or be in spaces between the adjacent bit line spacers 150.

The fence pattern 170 may fill a trench 170T in which side walls 170S1 and 170S2 are defined by the adjacent contact structures 160, and a bottom surface 170TBS is defined by the cell gate capping film 113.

The trench 170T may include a first trench 170T1, and a second trench 170T2 connected to the first trench 170T1. A first side wall 170S1 of the first trench 170T1 may be defined by a storage contact 162. A bottom surface of the first trench 170T1 may be defined by the cell gate capping film 113. That is, the bottom surface of the first trench 170T1 may be the bottom surface 170TBS of the trench 170T. The second side wall 170S2 of the second trench 170T2 may be defined by the contact silicide film 164 and the storage pad 166.

The bottom surface 170BS of the fence pattern 170 may be the bottom surface of the trench 170T. The bottom surface 170BS of the fence pattern 170 may be disposed below the bottom surface 162BS of the storage contact 162 (e.g., a distance between the bottom surface 170BS and a lower surface of the substrate 100 in the vertical direction is less than a distance between the bottom surface 162BS and the lower surface of the substrate 100 in the vertical). Here, the vertical direction refers to a direction perpendicular to one surface of the substrate 100 on which the bit line structure 140ST is disposed, and means a direction perpendicular to a plane including the first to third directions D1, D2, and D3 The bottom surface 170BS of the fence pattern 170 may be disposed between an upper surface 113US of the cell gate capping film 113 and a lower surface 113BS of the cell gate capping film 113. A part of the fence pattern 170 may enter or extend into the cell gate capping film 113.

The fence pattern 170 includes a spacer film 172 and a filling film 174.

The spacer film 172 may extend along part of the side walls 170S1 and 170S2 of the trench 170T and along the bottom surface 170TBS of the trench 170T. The spacer film 172 may extend along the first side wall 170S1 and the bottom surface 170TBS of the first trench 170T1. The filling film 174 may be disposed on the spacer film 172. The filling film 174 may at least partially fill or be in the trench 170T on the spacer film 172. That is, the first trench 170T1 may be filled with or include the spacer film 172 and the filling film 174, and the second trench 170T2 may be filled with or include the filling film 174.

The filling film 174 may be disposed between adjacent storage contacts 162, between adjacent contact silicide films 164, and between adjacent storage pads 166. The spacer film 172 is disposed between the filling film 174 and the storage contact 162, but is not disposed between the filling film 174 and the storage pad 166, and between the filling film 174 and the contact silicide film 164. The spacer film 172 may extend along the entire side surface of the storage contact 162 (i.e., the first side wall 170S1 of the trench 170T). The spacer film 172 may extend along the lower portion of the filling film 174 and the bottom surface of the filling film 174.

In the second direction D2, a first width W1 of the first trench 170T1 is greater than a second width W2 of the second trench 170T2. In the second direction D2, the width of the fence pattern 170 that at least partially fills or is in the first trench 170T1 is greater than the width of the fence pattern 170 that at least partially fills or is in the second trench 170T2. The width of the lower portion of the fence pattern 170 is greater than the width of the upper portion of the fence pattern 170.

A contact silicide film 164 and a storage pad 166 may be disposed on the upper surface of the spacer film 172. The spacer film 172 may overlap the contact silicide film 164 and the storage pad 166 in the vertical direction. The upper surface, the lower surface, the upper portion, the lower portion, and the bottom surface are defined on the basis of the vertical direction.

The width of the storage contact 162 at an interface between the contact silicide film 164 and the storage contact 162 is smaller than the width of the storage pad 166 at an interface between the contact silicide film 164 and the storage pad 166.

The spacer film 172 and the filling film 174 each include an insulating material. The spacer film 172 and the filling film 174 include different materials from each other. The spacer film 172 includes a material that has an etching selectivity to the filling film 174. For example, the spacer film 172 may include silicon oxide, and the filling film 174 may include silicon nitride.

Since the spacer film 172 is disposed between the storage contacts 162, a semiconductor memory device with reduced parasitic capacitance may be provided.

A pad separation pattern 180 may be formed on the storage pad 166 and the bit line structure 140ST. For example, the pad separation pattern 180 may be disposed on the cell line capping film 144.

The pad separation pattern 180 may define a region of the storage pad 166 that forms a plurality of isolated regions. The pad separation pattern 180 may separate the adjacent storage pads 166. The pad separation pattern 180 may not cover or overlap the upper surface of the storage pad 166.

The pad separation pattern 180 includes an insulating material. The pad separation pattern 180 may electrically separate or isolate the plurality of storage pads 166 from each other. For example, the pad separation pattern 180 may include at least one of a silicon oxide film, a silicon nitride film, a silicon oxynitride film, a silicon oxycarbonitride film, and a silicon carbonitride film.

An upper etching stop film 292 may be disposed on the pad separation pattern 180 and the storage pad 166. The upper etching stop film 292 may extend not only to the cell region 20 but also to the peri-region 24. The upper etching stop film 292 may include at least one of a silicon nitride film, a silicon carbonitride film, a silicon boron nitride (SiBN) film, a silicon oxynitride film, and a silicon oxycarbide film.

An information storage element 190 may be disposed on the storage pad 166. The information storage element 190 is connected to the storage pad 166. A part of the information storage element 190 may be disposed inside the upper etching stop film 292.

The information storage element 190 may include, for example, a capacitor. The information storage element 190 includes a lower electrode 191, a capacitor dielectric film 192, and an upper electrode 193. For example, the upper electrode 193 may be a plate upper electrode having a plate shape.

The lower electrode 191 may be disposed on the storage pad 166. The lower electrode 191 may have, for example, a pillar shape.

A capacitor dielectric film 192 is formed on the lower electrode 191. The capacitor dielectric film 192 may be formed along the profile of the lower electrode 191. An upper electrode 193 is formed on the capacitor dielectric film 192. The upper electrode 193 may cover or overlap the outer wall of the lower electrode 191. The upper electrode 193 may be a single film or include multiple films.

Each of the lower electrode 191 and the upper electrode 193 may include, for example, a doped semiconductor material, a conductive metal nitride (e.g., titanium nitride, tantalum nitride, niobium nitride or tungsten nitride, etc.), a metal (e.g., ruthenium, iridium, titanium, or tantalum, etc.), and conductive metal oxide (e.g., iridium oxide or niobium oxide, etc.).

The capacitor dielectric film 192 may include, for example, one of silicon oxide, silicon nitride, silicon oxynitride, a high dielectric constant material, and combinations thereof. In the semiconductor memory device according to some embodiments, the capacitor dielectric film 192 may include a stacked film structure in which zirconium oxide, aluminum oxide, and zirconium oxide are sequentially stacked. In the semiconductor memory device according to some embodiments, the capacitor dielectric film 192 may include a dielectric film that includes hafnium (Hf). In the semiconductor memory device according to some embodiments, the capacitor dielectric film 192 may have a stacked structure of a ferroelectric material film and a paraelectric material film.

A peri-gate structure 240ST may be disposed on the substrate 100 of the peri-region 24. The peri-gate structure 240ST may include a peri-gate insulating film 230, a peri-gate conductive film 240, and a peri-capping film 244, which are sequentially stacked on the substrate 100. The peri-gate structure 240ST may include a peri-spacer 245 which is disposed on the side wall of the peri-gate conductive film 240 and the side wall of the peri-capping film 244.

The peri-gate conductive film 240 may include first to third peri-conductive films 241, 242, and 243 that are sequentially stacked on the peri-gate insulating film 230. As an example, no additional conductive film may be disposed between the peri-gate conductive film 240 and the peri-gate insulating film 230. As another example, an additional conductive film, such as a work function conductive film, may be disposed between the peri-gate conductive film 240 and the peri-gate insulating film 230, unlike the shown example.

For example, the peri-gate conductive film 240 may have the same stacked structure as that of the cell conductive line 140. The thickness of the peri-gate conductive film 240 may be the same as the thickness of the cell conductive line 140 in the vertical direction.

The first peri-conductive film 241 may include the same material as the first cell conductive film 141. The second cell conductive film 242 may include the same material as the second cell conductive film 142. The third cell conductive film 243 may include the same material as the third cell conductive film 143.

The peri-gate insulating film 230 may include, for example, silicon oxide, silicon nitride, silicon oxynitride, or a high dielectric constant material having a higher dielectric constant than silicon oxide.

The peri-spacer 245 may include, for example, at least one of silicon nitride, silicon oxynitride, silicon oxide, silicon carbonitride, silicon oxycarbonitride, and combinations thereof. The peri-spacer 245 may be a single film, or the peri-spacer 245 may include multiple films.

The peri-capping film 244 may include, for example, at least one of a silicon nitride film, a silicon oxynitride, and a silicon oxide.

A lower etching stop film 250 may be disposed on the substrate 100. The lower etching stop film 250 may be formed along the profile of the peri-gate structure 240ST. The lower etching stop film 250 may include, for example, at least one of silicon nitride film, silicon oxynitride, silicon carbonitride, and silicon oxycarbonitride.

A cell interlayer insulating film 295 may be disposed on the lower etching stop film 250. For example, the cell interlayer insulating film 295 may be disposed on the cell region separation film 22. The cell interlayer insulating film 295 may be disposed between the dummy bit line structure 140STD and the peri-gate structure 240ST.

A first interlayer insulating film 291 is disposed on the peri-gate structure 240ST and the cell interlayer insulating film 295. The first interlayer insulating film 291 may cover or overlap the peri-gate structure 240ST. The first interlayer insulating film 291 may cover or overlap the upper surface of the cell interlayer insulating film 295 and the lower etching stop film 250 that protrudes or extends above the upper surface of the cell interlayer insulating film 295. The first interlayer insulating film 291 may include silicon nitride.

A peri interlayer insulating film 296 is disposed on the upper etching stop film 292. The peri interlay insulating film 296 covers a sidewall of the upper electrode 193. The peri interlayer insulating film 296 includes an insulating material.

A peri-wiring line 262 may be disposed on the first interlayer insulating film 291. The peri-wiring line 262 may include the same material as that of the storage pad 166. The pad separation pattern 180 may separate the peri-wiring line 262.

The pad separation pattern 180 may be formed at a position from which a part of the cell line capping film 144 is removed. In some embodiments, the pad separation pattern 180 may overlap the entire cell line capping film 144 of the dummy bit line structure 140STD in the vertical direction. The first interlayer insulating film 291 may not cover or overlap the dummy bit line structure 140STD.

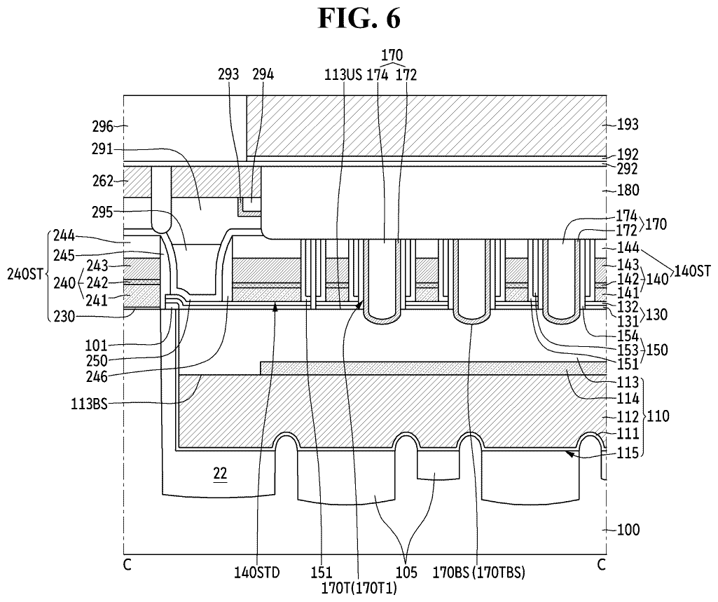

FIG. 6 is a cross-sectional view taken along the line C-C of FIG. 2.

Referring to FIG. 6, in the semiconductor device according to some embodiments, the pad separation pattern 180 may overlap a part of the cell line capping film 144 of the dummy bit line structure 140STD in the vertical direction. The first interlayer insulating film 291 may cover or overlap a part of the dummy bit line structure 140STD.

A first interlayer insulating film 291, a second interlayer insulating film 293, and a third interlayer insulating film 294 may be disposed on the dummy bit line structure 140STD. The second interlayer insulating film 293 and the third interlayer insulating film 294 may be disposed inside the first interlayer insulating film 291. The second interlayer insulating film 293 extends along the side walls and bottom surface of the trench in the first interlayer insulating film 291, but may not extend along the side walls of the trench defined by the pad separation pattern 180. The third interlayer insulating film 294 may fill or be in the trench on the second interlayer insulating film 293.

The second interlayer insulating film 293 and the third interlayer insulating film 294 may include different materials from each other. The second interlayer insulating film 293 may include the same material as the spacer film 172, and the third interlayer insulating film 294 may include the same material as the filling film 174.

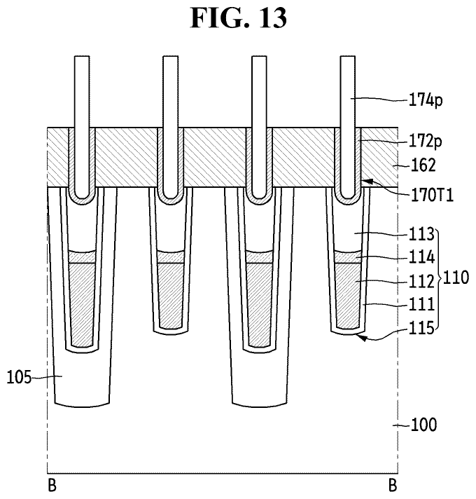

FIGS. 7 to 16 are intermediate stage diagrams for explaining a method for explaining a semiconductor memory device according to some embodiments. Among the explanations about the fabricating method, repeated contents of those explained using FIGS. 1 to 6 will be briefly explained or omitted.

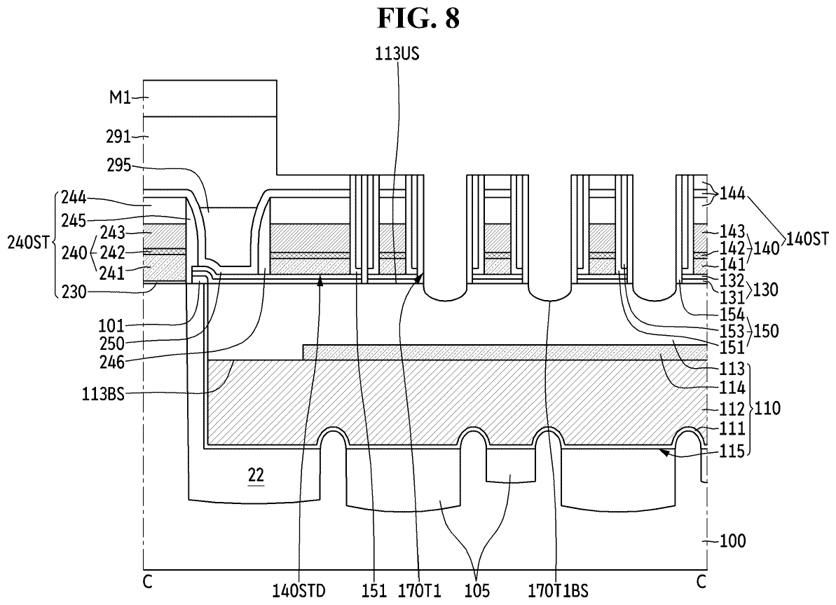

Referring to FIGS. 7 and 8, a substrate 100 including a cell region 20, a peri-region 24, and a cell region separation film 22 is provided.

The cell gate structure 110 may be formed inside the substrate 100 of the cell region 20. The cell gate structure 110 may extend long in the first direction D1. The cell gate structure 110 may include a cell gate trench 115, a cell gate insulating film 111, a cell gate electrode 112, a cell gate capping film 113, and a cell gate capping conductive film 114.

Subsequently, the cell insulating film 130 may be formed on the cell region 20. The cell insulating film 130 may expose the substrate 100 of the peri-region 24.

Subsequently, a cell conductive line 140 and a cell line capping film 144 may be formed on the substrate 100 of the cell region 20. That is, a plurality of bit line structures 140ST extending in the second direction D2 may be formed on the substrate 100 of the cell region 20.

The peri-gate conductive film 240 and the peri-capping film 244 may be formed, while the cell conductive line 140 and the cell line capping film 144 are being formed. A first mask pattern M1 that covers or overlaps the peri-region 24 (shown in FIG. 1) may be formed. The insulating material film including the peri-capping film 244, the lower etching stop film 250, and the first interlayer insulating film 291 may be patterned by the use of the first mask pattern M1 to form the cell line capping film 144.

A bit line contact 146 may be formed, while the cell conductive line 140 and the cell line capping film 144 are being formed.

A storage contact recess (a recess in which the storage contact 162 of FIG. 3 is disposed) may be formed, by using the bit line structure 140ST as an etching mask. The storage contact recess may be formed by removing the substrate 100 and the cell element separation film 105. A part of the bit line spacer 150 may be removed, while the storage contact recess is being formed.

Subsequently, a preliminary storage contact 162p may be formed on the upper surface of the substrate 100, the upper surface of the cell element separation film 105, the upper surface of the cell gate structure 110, and the storage recess. A second mask pattern M2 may be formed on the preliminary storage contact 162p. The preliminary storage contact 162p may be etched, using the second mask pattern M2 as a mask. The preliminary storage contact 162p may be etched to form the first trench 170T1. A bottom surface 170T1BS of the first trench 170T1 may be disposed below a bottom surface 163Pbs of the preliminary storage contact 163p. The bottom surface 170T1BS of the first trench 170T1 may be disposed between the upper surface 113US of the cell gate capping film 113 and the lower surface 113BS of the cell gate capping film 113.

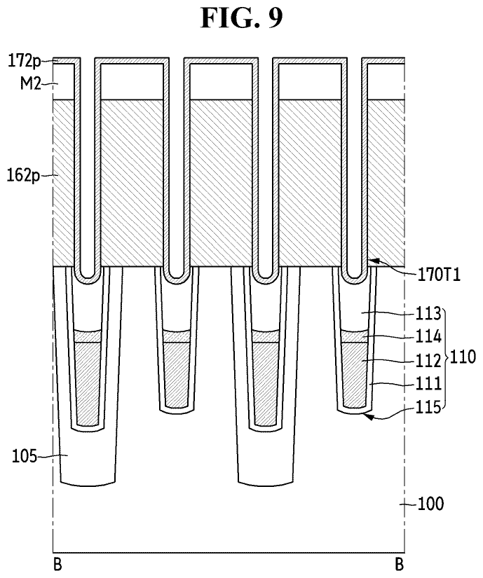

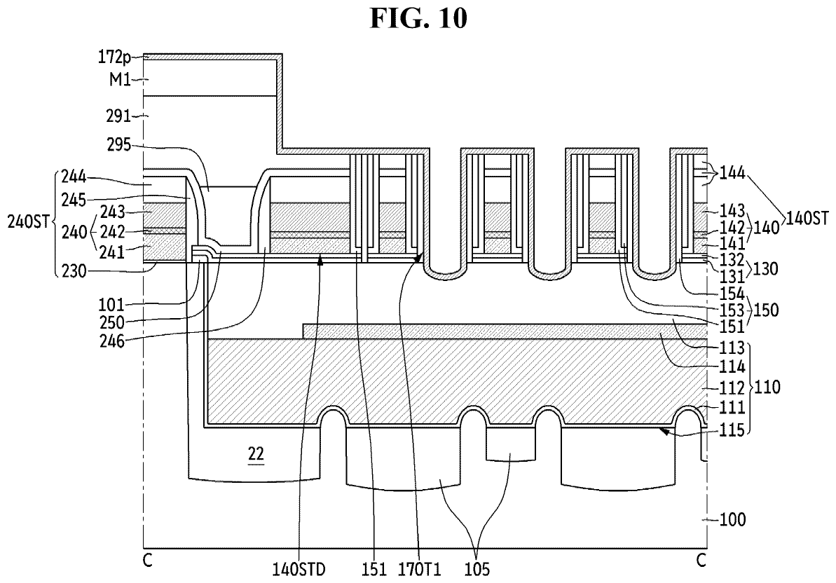

Referring to FIGS. 9 and 10, a preliminary spacer film 172p may be formed. The preliminary spacer film 172p may extend along a bottom surface of the first trench 170T1 and a side surface of the first trench 170T1. The preliminary spacer film 172p may extend along the first mask pattern M1, the second mask pattern M2, the first interlayer insulating film 291, the upper surface of the bit line structure 140ST, and the upper surface of the bit line spacer 150.

The preliminary spacer film 172p may be formed, for example, through an atomic layer deposition (ALD) process.

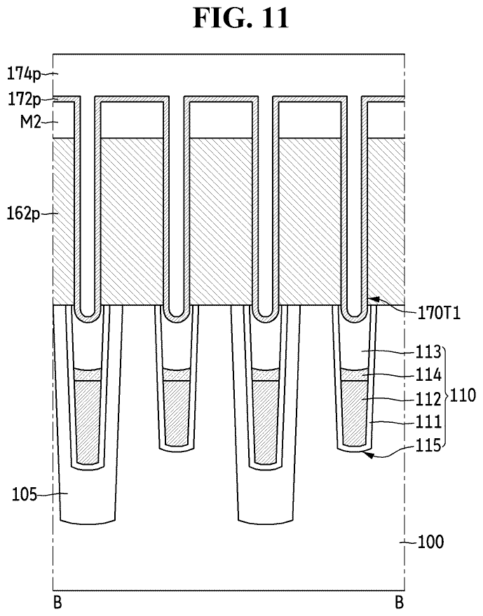

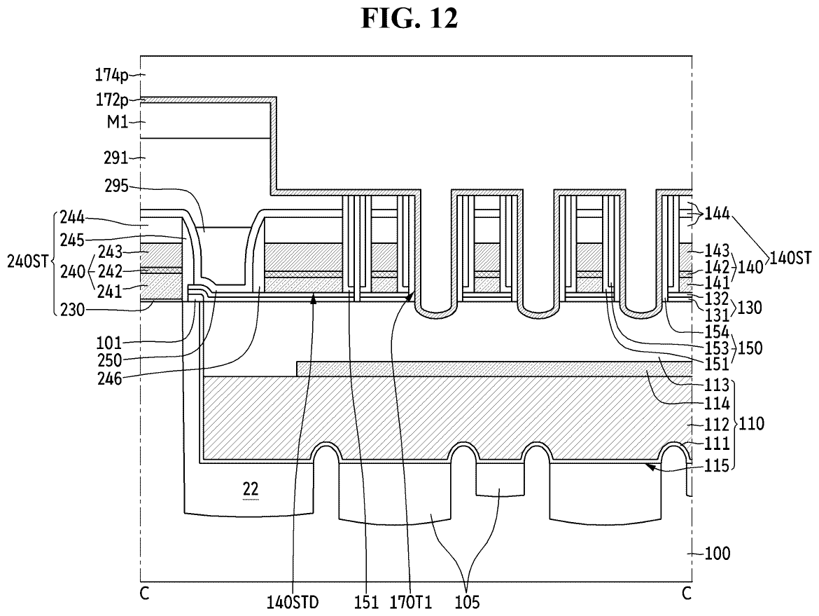

Referring to FIGS. 11 and 12, a preliminary filling film 174p may be formed on the preliminary spacer film 172p. The preliminary filling film 174p may cover or overlap the preliminary spacer film 172p. The preliminary filling film 174p may at least partially fill the first trench 170T1.

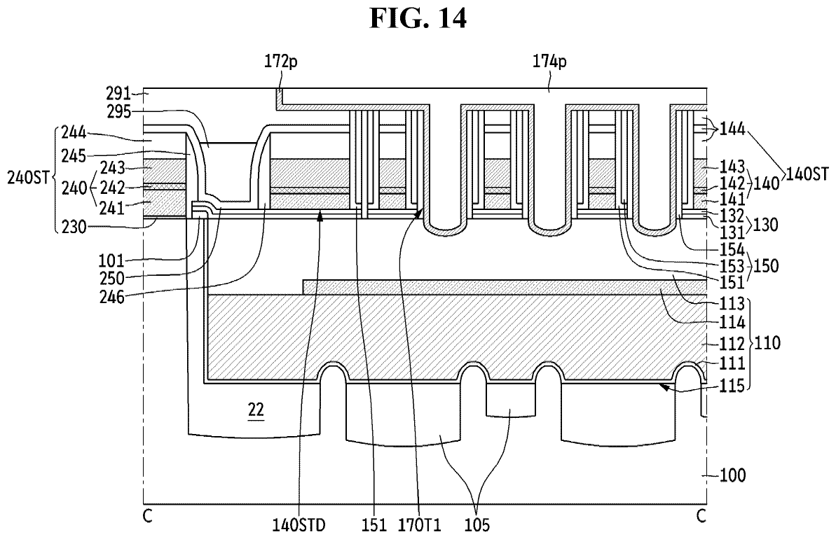

Referring to FIGS. 11 and 14, an upper portion of the preliminary spacer film 172p may be etched. For example, the upper portion of the preliminary spacer film 172p may be removed through an etch-back process to expose the second mask pattern M2.

The second mask pattern M2 may be removed. Accordingly, the upper surface of the preliminary storage contact 162p and the upper surface of the preliminary spacer film 172p may be exposed.

The storage contact 162 may then be formed by patterning the preliminary storage contact 162p. For example, the storage contact 162 may be formed by removing the upper portion of the preliminary storage contact 162p through the etch-back process. Accordingly, the side surface of the preliminary spacer film 172p may be exposed. The upper surface of the preliminary spacer film 172p and the upper surface of the preliminary filling film 164p may be disposed above the upper surface of the storage contact 162.

Next, the preliminary spacer film 172p may be patterned to expose the side surface of the preliminary filling film 164p. For example, an upper portion of the preliminary storage contact 162p may be removed through the etch-back process, and the upper surface of the preliminary spacer film 172p may be disposed below the upper surface of the preliminary filling film 164p. The preliminary spacer film 172p may be removed such that the upper surface of the storage contact 162 and the upper surface of the preliminary spacer film 172p are disposed on substantially the same plane. The upper surface of the preliminary spacer film 172p and the upper surface of the storage contact 162 may have a step difference depending on the process. For example, the upper surface of the preliminary spacer film 172p may be disposed above or below the upper surface of the storage contact 162.

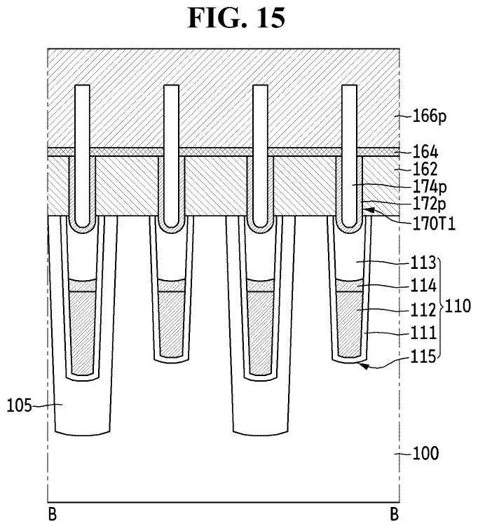

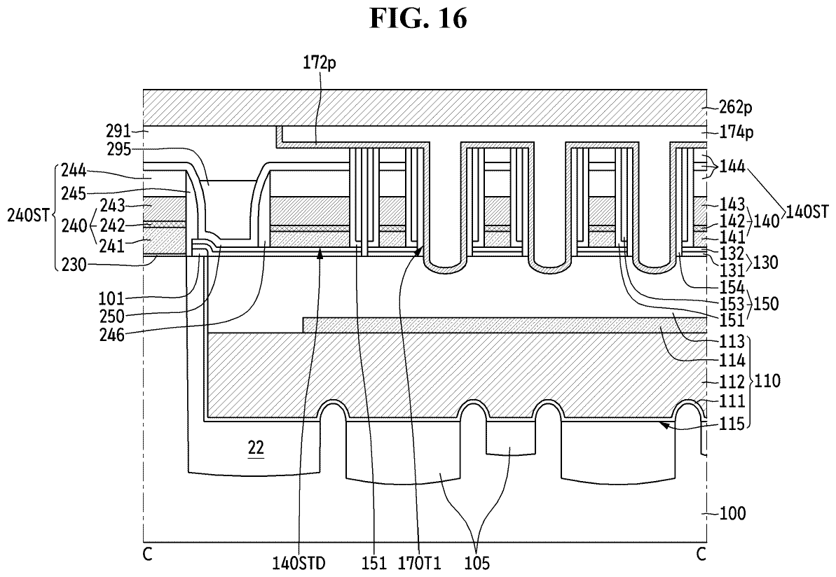

Referring to FIGS. 15 and 16, a preliminary storage pad 166p and a preliminary peri-wiring line 262p may be formed. The preliminary storage pad 166p may be formed on the storage contact 162. The contact silicide film 164 may be formed between the storage contact 162 and the preliminary storage pad 166p. The preliminary peri-wiring line 262p may be formed on the preliminary filling film 166p and the first interlayer insulating film 291.

In FIGS. 15 and 16, the contact silicide film 164 and the preliminary storage pad 166p are formed in the space in which the preliminary spacer film 172p is removed. That is, a space in which the storage pad 166 is formed may be secured. Therefore, when the space in which the storage pad 166 is formed is insufficient, a void generated inside the storage pad 166 and a discontinuation phenomenon of the storage pad 166 due to the void may be prevented or inhibited, and a semiconductor memory device having improved and/or enhanced reliability may be provided.

Referring to FIGS. 4 and 5, a pad separation pattern 180 may be formed. A peri-wiring line 262, a storage pad 166, and a fence pattern 170 may be formed by the pad separation pattern 180. When forming the pad separation pattern 180, the preliminary spacer film 172p and the preliminary filling film 174p on the dummy bit line structure 140STD may be removed in FIG. 14. That is, only the first interlayer insulating film 291 may remain on the dummy bit line structure 140STD. The information storage element 190 may be formed on the storage pad 166.

Referring to FIG. 6, when forming the pad separation pattern 180, the preliminary spacer film 172p and preliminary filling film 174p on the dummy bit line structure 140STD may remain in FIG. 14. The remaining preliminary spacer film 172p is the second interlayer insulating film 293, and the remaining preliminary filling film 174p is the third interlayer insulating film 294. That is, the second interlayer insulating film 293 and the third interlayer insulating film 294 may be formed on the dummy bit line structure 140STD depending on the position at which the pad separation pattern 180 is formed.

Depending on the formation position of the pad separation pattern 180, only the second interlayer insulating film 293 may be formed on the dummy bit line structure 140STD.

Further, when the first mask pattern M1 of FIG. 8 exposes a part of the cell interlayer insulating film 295, the preliminary spacer film 172p and the preliminary filling film 174p may be formed on the cell interlayer insulating film 295. Depending on the formation position of the pad separation pattern 180, the preliminary spacer film 172p and the preliminary filling film 174p may remain on the cell interlayer insulating film 295 and the dummy bit line structure 140STD, and the second interlayer insulating film 293 and the third interlayer insulating film 294 may be formed.

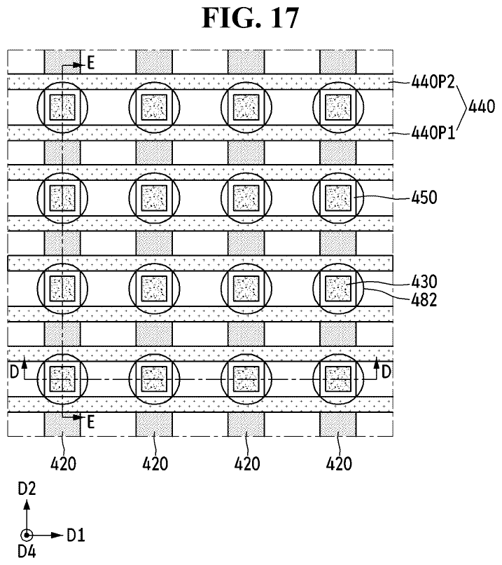

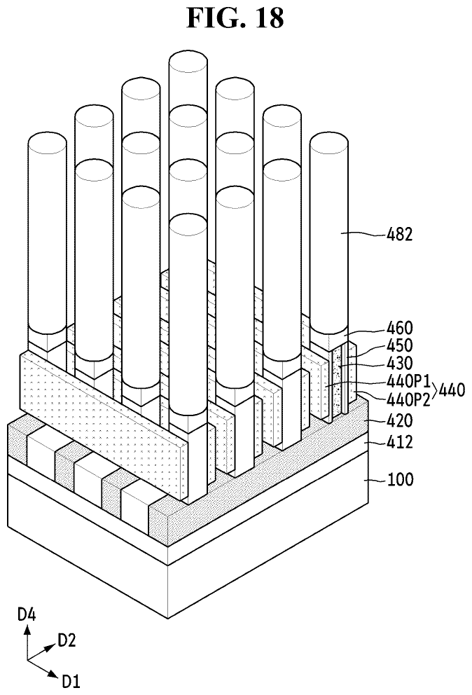

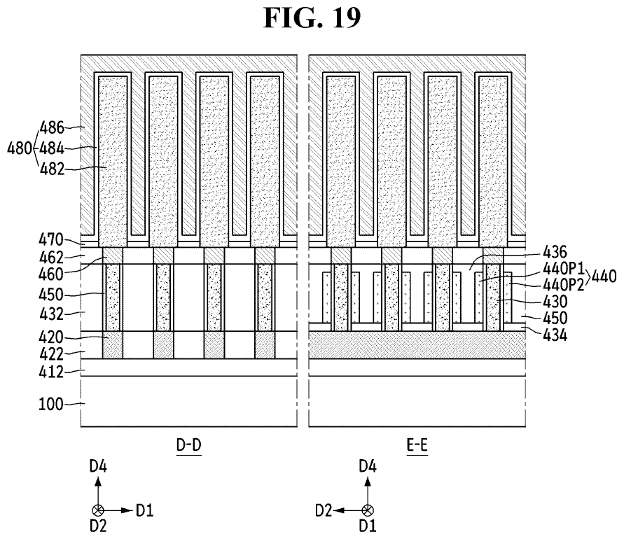

FIG. 17 is a layout diagram for explaining a semiconductor memory device according to some embodiments. FIG. 18 is a perspective view for explaining a semiconductor memory device according to some embodiments. FIG. 19 is a cross-sectional view taken along lines D-D and E-E of FIG. 17. For reference, FIG. 17 may be an enlarged view of the cell region 20 of FIG. 1.

Referring to FIGS. 17 to 19, a semiconductor memory device according to some embodiments may include a substrate 100, a plurality of first conductive lines 420, a channel layer 430, a gate electrode 440, a gate insulating film 450, and a capacitor 480.

The semiconductor memory device according to some embodiments may be a memory device including a vertical channel transistor (VCT). The vertical channel transistor may refer to a structure in which the channel length of the channel layer 430 extends from the substrate 100 along the vertical direction (e.g., a fourth direction D4).

A lower insulating layer 412 may be disposed on the substrate 100. A plurality of first conductive lines 420 may be spaced apart from each other in the first direction D1 and extend in the second direction D2 on the lower insulating layer 412. A plurality of first insulating patterns 422 may be disposed on the lower insulating layer 412 to fill the space between the plurality of first conductive lines 420. The plurality of first insulating patterns 422 may extend in the second direction D2. The upper surfaces of the plurality of first insulating patterns 422 may be disposed at the same level as the upper surfaces of the plurality of first conductive lines 420. The plurality of first conductive lines 420 may function as bit lines.

The plurality of first conductive lines 420 may include a doped semiconductor material, metal, conductive metal nitride, conductive metal silicide, conductive metal oxide, or combinations thereof. For example, the plurality of first conductive lines 420 may be may include, but is not limited to, doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx or a combination thereof. The plurality of first conductive lines 420 may include a single layer or multiple layers of the above-mentioned materials. In some embodiments, the plurality of first conductive lines 420 may include graphene, carbon nanotube or a combination thereof.

The channel layers 430 may be arranged in the form of a matrix in which they are disposed apart from each other in the first direction D1 and the second direction D2 on the plurality of first conductive lines 420. The channel layer 430 may have a first width along the first direction D1 and a first height along the fourth direction D4, and the first height may be greater than the first width. Here, the fourth direction D4 may be a direction which intersects the first direction D1 and the second direction D2, and is perpendicular to, for example, the upper surface of the substrate 100. For example, the first height may be, but is not limited to, about 2 to 10 times the first width. A bottom portion of the channel layer 430 may function as a third source/drain region (not shown), an upper portion of the channel layer 430 may function as a fourth source/drain region (not shown), and a part of the channel layer 430 between the third and fourth source/drain regions may function as a channel region (not shown).

As an example, the channel layer 430 may include an oxide semiconductor, and the oxide semiconductor may include, for example, InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O or combinations thereof. The channel layer 430 may include a single layer or multi layers of the oxide semiconductor. In some embodiments, the channel layer 430 may have a bandgap energy that is greater than the bandgap energy of silicon. For example, the channel layer 430 may have a bandgap energy of about 1.5 eV to 5.6 eV. For example, the channel layer 430 may have optimum channel performance when having the bandgap energy of about 2.0 eV to 4.0 eV. For example, the channel layer 430 may be polycrystalline or amorphous. As another example, the channel layer 430 may include graphene, carbon nanotube or a combination thereof. As yet another example, the channel layer 430 may include a silicon-based semiconductor material. The channel layer 430 may include a single crystal semiconductor material, and for example, single crystal silicon or single crystal silicon-germanium.

The gate electrode 440 may extend in the first direction D1 on both side walls of the channel layer 430. The gate electrode 440 may include a first sub-gate electrode 440P1 that faces a first side wall of the channel layer 430, and a second sub-gate electrode 440P2 that faces a second side wall opposite to the first side wall of the channel layer 430. As the single channel layer 430 is disposed between the first sub-gate electrode 440P1 and the second sub-gate electrode 440P2, the semiconductor device may have a dual gate transistor structure. However, the technical idea of the present disclosure is not limited thereto, as the second sub-gate electrode 440P2 may be omitted, and only the first sub-gate electrode 440P1 that faces the first side wall of the channel layer 430 may be formed to realize a single gate transistor structure. The materials included in the gate electrode 440 may be the same as description of the cell gate electrode 112.

The gate insulating film 450 at least partially surrounds side walls of the channel layer 430 and may be interposed between the channel layer 430 and the gate electrode 440. For example, as shown in FIG. 11, the entire side wall of the channel layer 430 may be at least partially surrounded by the gate insulating film 450, and a part of the side wall of the gate electrode 440 may be in contact with the gate insulating film 450. In other embodiments, the gate insulating film 450 extends in the extending direction of the gate electrode 440 (i.e., the first direction D1), and only the two side walls that face the gate electrode 440 among the side walls of the channel layer 430 may be in contact with the gate insulating film 450. In some embodiments, the gate insulating film 450 may be made up of a silicon oxide film, a silicon oxynitride film, a high dielectric constant material having a higher dielectric constant than the silicon oxide film, or a combination thereof.

A plurality of second insulating patterns 432 may extend on the plurality of first insulating patterns 422 along the second direction D2. The channel layer 430 may be disposed between two adjacent second insulating patterns 432 among the plurality of second insulating patterns 432. Further, the first buried layer 434 and the second buried layer 436 may be disposed in a space between two adjacent channel layers 430, between two adjacent second insulating patterns 432. The first buried layer 434 may be disposed at the bottom portion of the space between two adjacent channel layers 430. The second buried layer 436 may be formed to at least partially fill the remainder of the space between two adjacent channel layers 430 on the first buried layer 434. The upper surface of the second buried layer 436 may be disposed at the same level as the upper surface of the channel layer 430, and the second buried layer 436 may cover the upper surface of the gate electrode 440. In contrast, the plurality of second insulating patterns 432 may be formed of a continuous material layer with the plurality of first insulating patterns 422, or the second buried layer 436 may be formed of a continuous material layer with the first buried layer 434.

Capacitor contacts 460 may be disposed on the channel layer 430. The capacitor contacts 460 are disposed to vertically overlap the channel layer 430, and may be arranged in the form of a matrix in which they are spaced apart from each other in the first direction D1 and the second direction D2. The capacitor contacts 460 may be made up of, but not limited to, doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx or a combination thereof. An upper insulating film 462 may at least partially surround the side walls of the capacitor contacts 460 on the plurality of second insulating patterns 432 and the second buried layer 436.

An etching stop film 470 may be disposed on the upper insulating layer 462, and a capacitor 480 may be disposed on the etching stop film 470. The capacitor 480 may include a second lower electrode 482, a second capacitor dielectric film 484, and a second upper electrode 486. The second lower electrode 482 penetrates or extends into the etching stop film 470 and may be electrically connected to the upper surface of the capacitor contact 460. The second lower electrode 482 may be formed, but not limited to, in a pillar type extending in the fourth direction D4. In some embodiments, the second lower electrodes 482 are disposed to vertically overlap the capacitor contacts 460, and may be arranged in the form of a matrix in which they are spaced apart from each other in the first direction D1 and the second direction D2. In some embodiments, a landing pad (not shown) is further disposed between the capacitor contact 460 and the second lower electrode 482, and the second lower electrode 482 may be arranged in a hexagonal shape.

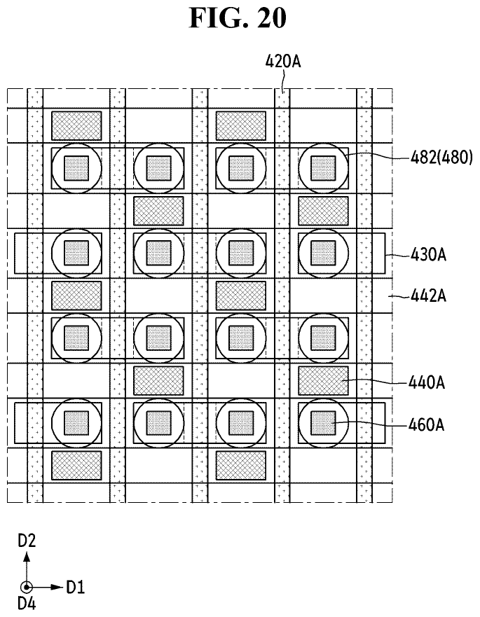

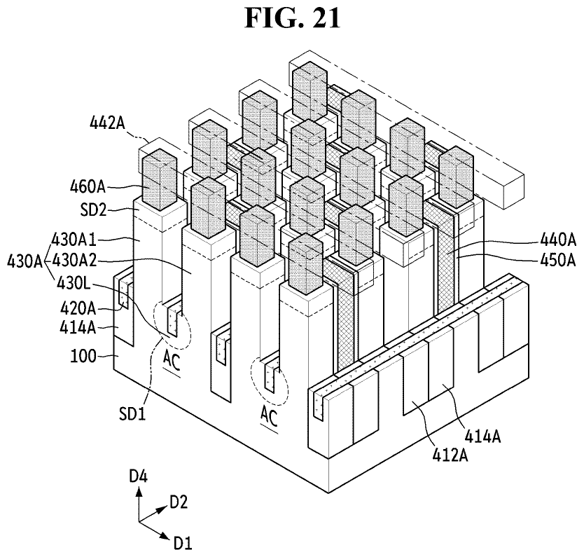

FIG. 20 is a layout diagram for explaining a semiconductor memory device according to some embodiments. FIG. 21 is a perspective view for explaining the semiconductor memory device according to some embodiments.

Referring to FIGS. 20 and 21, the semiconductor memory device according to some embodiments may include a substrate 100, a plurality of first conductive lines 420A, a channel structure 430A, a contact gate electrode 440A, a plurality of second conductive lines 442A, and a capacitor 480. The semiconductor memory device according to some embodiments may be a memory device that includes a vertical channel transistor VCT.

A plurality of active regions AC may be defined by the first element separation pattern 412A and the second element separation pattern 414A on the substrate 100. The channel structure 430A may be disposed in each active region AC, and the channel structure 430A may include a first active pillar 430A1 and a second active pillar 430A2 each extending in the vertical direction, and a connecting portion 430L connected to a bottom portion of the first active pillar 430A1 and a bottom portion of the second active pillar 430A2. A first source/drain region SD1 may be disposed inside the connecting portion 430L, and a second source/drain region SD2 may be disposed above the first and second active pillars 430A1 and 430A2. Each of the first active pillar 430A1 and the second active pillar 430A2 may form an independent unit memory cell.

The plurality of first conductive lines 420A may extend in a direction intersecting each of the plurality of active regions AC, and may extend, for example, in the second direction D2. One first conductive line 420A among the plurality of first conductive lines 420A may be disposed on the connecting portion 430L between the first active pillar 430A1 and the second active pillar 430A2. One first conductive line 420A may be disposed on the first source/drain region SD1. The other first conductive line 420A adjacent to the one first conductive line 420A may be disposed between the two channel structures 430A. One first conductive line 420A among the plurality of first conductive lines 420A may function as a common bit line included in the two unit memory cells constituted by the first active pillar 430A1 and the second active pillar 430A2 disposed on both sides of the one first conductive line 420A.

One contact gate electrode 440A may be disposed between the two channel structures 430A adjacent to each other in the second direction D2. For example, the contact gate electrode 440A may be disposed between the first active pillar 430A1 included in one channel structure 430A and the second active pillar 430A2 of the channel structure 430A adjacent thereto. One contact gate electrode 440A may be shared by the first active pillar 430A1 and the second active pillar 430A2 disposed on both side walls thereof. A gate insulating film 450A may be disposed between the contact gate electrode 440A and the first active pillar 430A1, and between the contact gate electrode 440A and the second active pillar 430A2. The plurality of second conductive lines 442A may extend in the first direction D1 on the upper surface of the contact gate electrode 440A. The plurality of second conductive lines 442A may function as word lines of the semiconductor device.

A capacitor contact 460A may be disposed on the channel structure 430A. The capacitor contact 460A may be disposed on the second source/drain region SD2, and the capacitor 480 may be disposed on the capacitor contact 460A.

Although the embodiments of the present disclosure have been described above with reference to the accompanying drawings, the present disclosure is not limited to the above embodiments, and may be fabricated in various different forms. Those skilled in the art will appreciate that the present disclosure may be embodied in other specific forms without changing the technical spirit or essential features of the present disclosure. Accordingly, the above-described embodiments should be understood in all respects as illustrative and not restrictive.

What is claimed is:

1. A semiconductor memory device comprising:
a substrate;
a plurality of contact structures on the substrate; and
a fence pattern that separates the plurality of contact structures from each other, wherein:
each of the plurality of contact structures comprises a storage contact on the substrate, and a storage pad on the storage contact,
the fence pattern comprises a filling film and a spacer film comprising a material that is different from a material of the filling film,
the spacer film is between the filling film and the storage contact, and
the spacer film is not between the filling film and the storage pad.

2. The semiconductor memory device of claim 1, wherein:
the plurality of contact structures further comprise a contact silicide film between the storage contact and the storage pad, and
the spacer film is not between the filling film and the contact silicide film.

3. The semiconductor memory device of claim 1, further comprising:
a plurality of cell gate structures that extend in a first direction, are spaced apart from each other in a second direction, and are on the substrate,
wherein each of the plurality of cell gate structures comprises a cell gate electrode and a cell gate capping film on the cell gate electrode, and
wherein a distance between a bottom surface of the fence pattern and a lower surface of the substrate in a direction perpendicular to the lower surface of the substrate is less than a distance between an upper surface of the cell gate capping film and the lower surface of the substrate in the direction.

4. The semiconductor memory device of claim 1, wherein the spacer film extends along a bottom surface of the filling film.

5. The semiconductor memory device of claim 1, wherein the spacer film overlaps the storage pad in a direction perpendicular to an upper surface of the substrate.

6. The semiconductor memory device of claim 1, further comprising:
a plurality of bit line structures that are spaced apart in a first direction and extend in a second direction, and
a plurality of bit line spacers on the substrate,
wherein each of the plurality of bit line spacers is on a side wall of a respective one of the plurality of bit line structures,
wherein the fence pattern is between ones of the plurality of bit line spacers, and
wherein the spacer film extends along each of the plurality of bit line spacers.

7. The semiconductor memory device of claim 1, wherein a distance between a bottom surface of the fence pattern and a lower surface of the substrate in a direction perpendicular to a lower surface of the substrate is less than a distance between a bottom surface of the storage contact and the lower surface of the substrate in the direction.

8. The semiconductor memory device of claim 1, wherein the spacer film extends along an entirety of a side surface of the storage contact.

9. The semiconductor memory device of claim 1, further comprising an information storage element electrically connected to the storage pad.

10. The semiconductor memory device of claim 9, wherein the information storage element comprises a lower electrode electrically connected to the storage pad, a capacitor dielectric film on the lower electrode, and a plate upper electrode on the capacitor dielectric film.

11. A semiconductor memory device comprising:
a substrate;
a cell gate structure that extends in a first direction and comprises a cell gate electrode and a cell gate capping film that are in the substrate;
a plurality of contact structures on the substrate; and
a fence pattern that is on the cell gate structure and is in a trench that comprises side walls that are defined by the plurality of contact structures and a bottom surface defined by the cell gate capping film,
wherein the fence pattern comprises a spacer film that extends along a first part of the side walls of the trench and a bottom surface of the trench, and
wherein the fence pattern comprises a filling film that is in the trench and is on the spacer film.

12. The semiconductor memory device of claim 11, wherein the spacer film comprises a material having an etching selectivity with respect to the filling film.

13. The semiconductor memory device of claim 11, wherein:
each of the plurality of contact structures comprises a storage contact on the substrate and a storage pad on the storage contact, and
the spacer film does not extend along a second part of side walls of the trench defined by the storage pad.

14. The semiconductor memory device of claim 11, wherein the bottom surface of the trench is between an upper surface of the cell gate capping film and a lower surface of the cell gate capping film.

15. The semiconductor memory device of claim 11, wherein:
each of the plurality of contact structures comprises a storage contact on the substrate, a storage pad on the storage contact, and a contact silicide film between the storage contact and the storage pad, and
a width of the storage contact at an interface between the contact silicide film and the storage contact in the first direction is less than a width of the storage pad at an interface between the contact silicide film and the storage pad in the first direction.

16. The semiconductor memory device of claim 11, wherein:
the trench comprises a first portion having a first width in the first direction and a second portion adjacent to the first portion and having a second width in the first direction that is less than the first width,
the spacer film extends along a side wall of the first portion and a bottom surface of the first portion, and
the spacer film does not extend along a side wall of the second portion.

17. A semiconductor memory device comprising:
a substrate that comprises a cell region and a peri-region;
a cell region separation film that defines the cell region in the substrate;
a cell gate structure that extends in a first direction parallel to a lower surface of the substrate and is in the cell region of the substrate;
a plurality of contact structures on the substrate; and
a fence pattern that is on the cell gate structure and between the plurality of contact structures, wherein:
each of the plurality of contact structures comprises a storage contact on the substrate and a storage pad on the storage contact,
a distance between a bottom surface of the fence pattern and a lower surface of the substrate in a second direction perpendicular to the lower surface of the substrate is less than a distance between a bottom surface of the storage contact and the lower surface of the substrate in the second direction,
the fence pattern comprises a filling film between the plurality of contact structures,
the fence pattern comprises a spacer film that is between the filling film and the storage contact and is not between the filling film and the storage pad, and
the spacer film overlaps the storage pad in the second direction.

18. The semiconductor memory device of claim 17, comprising:
a bit line structure that extends in a third direction parallel to the lower surface of the substrate and is on the cell region of the substrate,
a dummy bit line structure that extends in the third direction, is adjacent to the peri-region, and is on the cell region of the substrate,
a peri-gate structure on the peri-region of the substrate,
a first interlayer insulating film on the peri-gate structure and the dummy bit line structure, and
a second interlayer insulating film that is in the first interlayer insulating film and is on the dummy bit line structure.

19. The semiconductor memory device of claim 18, wherein the second interlayer insulating film and the spacer film comprise a same material.

20. The semiconductor memory device of claim 18, further comprising:
a third interlayer insulating film that is in the first interlayer insulating film and is on the dummy bit line structure,
wherein the third interlayer insulating film and the filling film comprise a same material.
